(19) United States
(12) Patent Application Publication
(10) Pub. No.: US 2025/0169340 A1
(43) Pub. Date: May 22, 2025

(54) DISPLAY PANEL AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Xiaoxi SUN, Hefei (CN); Xuejing ZHU, Hefei (CN); Yuan YAO, Hefei (CN); Bo RAO, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/737,063

(22) Filed: Jun. 7, 2024

(30) Foreign Application Priority Data
Nov. 16, 2023 (CN) 202311550470.0

(51) Int. Cl. H10K 59/80; H10K 59/122; H10K 59/131; H10K 59/40

(52) U.S. Cl. CPC H10K 59/8792; H10K 59/122; H10K 59/131; H10K 59/40; H10K 59/873

(57) ABSTRACT

A display panel and a display apparatus. The display panel includes a display area and a non-display area, and the display panel further includes: a base plate; a first electrode layer including a first electrode; a light-emitting layer including a light-emitting unit; an isolation structure located in the display area and arranged around at least a portion of the light-emitting unit; a shielding structure including a first shielding structure and at least one second shielding structure, at least a portion of the first shielding structure being arranged in the same layer as the isolation structure, and the second shielding structure being located in a different film layer from the first shielding structure; and a touch control component, at least a portion of the touch control component being located at a side of the shielding structure away from the base plate.

### CROSS REFERENCE TO RELATED APPLICATION

The present application claims priority to Chinese Patent Application No. 202311550470.0 filed on Nov. 16, 2023, which is incorporated herein by reference in its entirety.

### TECHNICAL FIELD

The present application relates to the field of display technology, and particularly to a display panel and a display apparatus.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the performance of current OLED display products needs to be improved.

### SUMMARY

Embodiments of the present application provide a display panel and a display apparatus, aiming to reduce mutual interference between the touch control signals and other signals in the display panel.

Some embodiments of a first aspect of the present application provide a display panel with a display area and a non-display area, the display panel includes: a base plate including at least one of a signal line or a driving circuit in the non-display area; a first electrode layer arranged at one side of the base plate and including a first electrode located in the display area; a light-emitting layer including a light-emitting unit located at a side of the first electrode away from the base plate; an isolation structure arranged at a side of the base plate facing the first electrode layer, the isolation structure being located in the display area and arranged around at least a portion of the light-emitting unit; a shielding structure located in the non-display area and including a first shielding structure and at least one second shielding structure that are electrically connected with each other, at least a portion of the first shielding structure being arranged in the same layer as the isolation structure, and the second shielding structure being located in a different film layer from the first shielding structure; and a touch control component, at least a portion of the touch control component being located at a side of the shielding structure away from the base plate.

Some embodiments of a second aspect of the present application provide a display apparatus including the display panel according to any of the above implementation.

The display panel according to the embodiments of the present application includes the display area and the non-display area, and the display panel further includes the base plate, the first electrode layer, the isolation structure, the light-emitting layer, the shielding structure, and the touch control component. The first electrode layer is arranged at one side of the base plate and includes the first electrode located in the display area, the light-emitting layer includes the light-emitting unit located at a side of the first electrode away from the base plate, and the first electrode may be configured to participate in driving the light-emitting unit to emit light. The isolation structure is arranged at a side of the base plate facing the first electrode layer, the isolation structure is located in the display area and arranged around at least a portion of the light-emitting unit, so that the isolation structure can be used to divide the sub-pixels of the display panel.

The shielding structure is located in the non-display area, and at least a portion of the touch control component is arranged at a side of the shielding structure away from the base plate, so that the shielding structure can better prevent the signal of the signal line or the driving circuit in the base plate from being transmitted to the touch control component, which is beneficial to reducing mutual interference between the signal in the base plate and the touch control signal in the touch control component. At least a portion of the first shielding structure is arranged in the same layer as the isolation structure, so that at least a portion of the first shielding structure and the isolation structure can be manufactured in a same process step, and thus not only mutual interference between the touch control signals and other signals in the display panel can be reduced through the first shielding structure, but also the manufacturing process of the display panel can be simplified, so as to increase the manufacturing efficiency of the display panel.

### BRIEF DESCRIPTION OF THE DRAWINGS

In order to more clearly illustrate the technical solutions of the embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 shows a schematic structural diagram of a display panel according to an embodiment of the present application;

FIG. 2 shows a partial schematic structural diagram of a first shielding structure and an isolation structure according to an embodiment of the present application;

FIG. 3 shows a partial sectional view of a display panel according to an embodiment of the present application;

FIG. 4 shows a partial schematic structural diagram of a first shielding structure and an isolation structure according to another embodiment of the present application;

FIG. 5 shows a partial sectional view of a display panel according to another embodiment of the present application;

FIG. 6 shows a partial sectional view of a display panel according to yet another embodiment of the present application;

FIG. 7 shows a partial schematic structural diagram of a shielding structure according to an embodiment of the present application;

FIG. 8 shows a partial sectional view of a display panel according to yet another embodiment of the present application;

FIG. 9 shows a partial schematic structural diagram of a second pixel definition portion according to an embodiment of the present application;

FIG. 10 shows a partial sectional view of a display panel according to yet another embodiment of the present application.

### REFERENCE NUMERALS

10, display panel; 10a, touch control component; 10b, via;
100, base plate; 110, substrate; 120, driving circuit layer; 121, first insulating layer; 122, second insulating layer; 123, third insulating layer; 124, transistor; 124a, gate; 124b, source/drain; 125, storage capacitor; 125a, first electrode plate; 125b, second electrode plate; 130, planarization layer;
200, first electrode layer; 210, first electrode;
300, pixel definition layer; 310, first pixel definition portion; 311, pixel opening; 320, second pixel definition portion; 330, third pixel definition portion; 340, through hole;
400, isolation structure; 400a, isolation opening; 410, isolation portion; 410a, first end portion; 410b, second end portion; 411, first isolation portion; 412, second isolation portion; 420, electrically conductive portion;
500, shielding structure; 510, first shielding structure; 510a, shielding opening; 511, first sub-portion; 511a, third end portion; 511b, fourth end portion; 511c, first shielding portion; 511d, second shielding portion; 512, second sub-portion; 520, second shielding structure; 600, light-emitting layer; 610, light-emitting unit;
700, second electrode layer; 710, second electrode;
810, first encapsulation layer; 820, second encapsulation layer; 821, second encapsulation portion; 830, third encapsulation layer;
900, dam; 910, first dam layer; 920, second dam layer;
AA, display area;
NA, non-display area;
X, thickness direction;
L1, first spacing;
L2, second spacing;
L3, third spacing.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

It should be understood that when describing the structure of a component, if a layer/area is referred to as being “on” or “above” another layer/region, it may mean that the layer/area is directly on the other layer/region or that other layers/regions may be included between the layer/area and the other layer/area. Moreover, if the component is turned over, the layer/region will be “below” or “under” the other layer/region.

The embodiments of the present application provide a display panel and a display apparatus, and various embodiments of the display panel and the display apparatus will be described below in connection with the accompanying drawings.

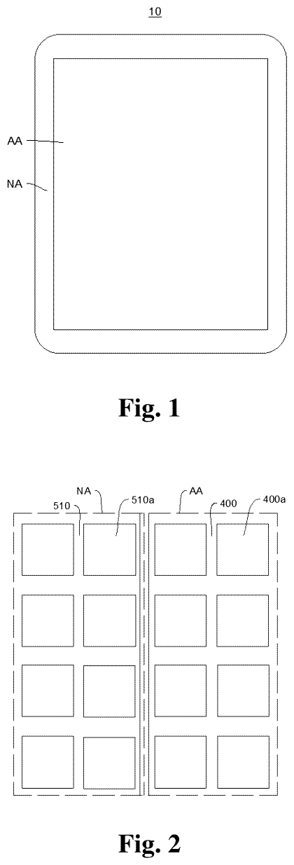

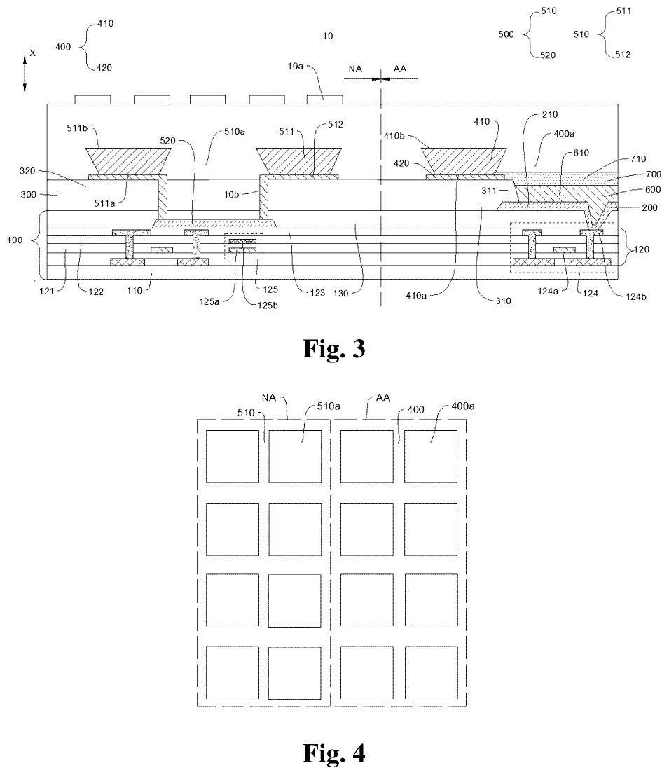

FIG. 1 shows a schematic structural diagram of a display panel 10 according to an embodiment of the present application, FIG. 2 shows a partial schematic structural diagram of a first shielding structure 510 and an isolation structure 400 according to an embodiment of the present application, and FIG. 3 shows a partial sectional view of a display panel 10 according to an embodiment of the present application. In the figures, the direction X is a thickness direction of the display panel 10.

The embodiments of the present application provide a display panel 10, which may be an Organic Light Emitting Diode (OLED) display panel 10.

As shown in FIGS. 1 to 3, the embodiments of the first aspect the present application provide a display panel 10 with a display area AA and a non-display area NA, and the display panel 10 includes: a base plate 100 including at least one of a signal line or a driving circuit in the non-display area NA; a first electrode layer 200 arranged at one side of the base plate 100 and including a first electrode 210 located in the display area AA; a light-emitting layer 600 including a light-emitting unit 610 located at a side of the first electrode 210 away from the base plate 100; an isolation structure 400 arranged at a side of the base plate 100 facing the first electrode layer 200, the isolation structure 400 being located in the display area AA and arranged around at least a portion of the light-emitting unit 610; a shielding structure 500 located in the non-display area NA and including a first shielding structure 510 and at least one second shielding structure 520 that are electrically connected with each other, at least a portion of the first shielding structure 510 being arranged in the same layer as the isolation structure 400, and the second shielding structure 520 being located in a different film layer from the first shielding structure 510; and a touch control component 10a, at least a portion of the touch control component 10a being located at a side of the shielding structure 500 away from the base plate 100.

The display panel 10 according to the embodiments of the present application includes the display area AA and the non-display area NA, and the display panel 10 further includes the base plate 100, the first electrode layer 200, the isolation structure 400, the light-emitting layer 600, the shielding structure 500, and the touch control component 10a. The first electrode layer 200 is arranged at one side of the base plate 100 and includes the first electrode 210 located in the display area AA, the light-emitting layer 600 includes the light-emitting unit 610 located at a side of the first electrode 210 away from the base plate 100, and the first electrode 210 may be configured to participate in driving the light-emitting unit 610 to emit light. The isolation structure 400 is arranged at a side of the base plate 100 facing the first electrode layer 200, the isolation structure 400 is located in the display area AA and arranged around at least a portion of the light-emitting unit 610, so that the isolation structure 400 can be used to divide the sub-pixels of the display panel 10.

The shielding structure 500 is located in the non-display area NA, and at least a portion of the touch control component 10a is arranged at a side of the shielding structure 500 away from the base plate 100, so that the shielding structure 500 can better prevent the signal in the base plate 100 from being transmitted to the touch control component 10a, which is beneficial to reducing mutual interference between the signal of the signal line or the driving circuit in the base plate 100 and the touch control signal in the touch control component 10a. At least a portion of the first shielding structure 510 is arranged in the same layer as the isolation structure 400, so that at least a portion of the first shielding structure 510 and the isolation structure 400 can be manufactured in a same process step, and thus not only mutual interference between the touch control signals and other signals in the display panel 10 can be reduced through the first shielding structure 510, but also the manufacturing process of the display panel 10 can be simplified, so as to increase the manufacturing efficiency of the display panel 10.

In some embodiments of the present application, the shielding structure 500 is an electrically conductive shielding structure, and the first shielding structure 510 and the second shielding structure 520 may be further electrically connected with each other, so that a capacitor is less likely to be generated between the first shielding structure 510 and the second shielding structure 520 that are located in different film layers, and the shielding structure 500 itself is less likely to interfere with the touch control signals in the touch control component 10a and the signals in the base plate 100, and thus the working reliability of the display panel 10 can be improved.

In some embodiments of the present application, the non-display area NA of the display panel 10 may be arranged around at least a portion of the display area AA. For example, the non-display area NA may be located at a frame of the display panel 10.

Optionally, the display panel 10 may further include a second electrode layer 700 located at a side of the light-emitting layer 600 away from the first electrode layer 200, and the second electrode layer 700 may include a second electrode 710 located at a side of the light-emitting unit 610 away from the first electrode 210. Optionally, the isolation structure 400 may be further arranged around at least a portion of the second electrode 710.

Optionally, the light-emitting unit 610 may include a Hole Inject Layer (HIL), a Hole Transport Layer (HTL), a light-emitting structure, an Electron Inject Layer (EIL), and an Electron Transport Layer (HTL).

Optionally, the first electrode layer 200 and the second electrode layer 700 may be pixel electrode layers. Herein, one of the first electrode 210 and the second electrode 710 may be used as an anode, and the other one of the first electrode 210 and the second electrode 710 may be used as a cathode, so as to drive the light-emitting unit 610 to emit light. In the embodiments of the present application, for example, the first electrode 210 is the anode of the display panel 10, and the second electrode 710 is the cathode of the display panel 10.

In some embodiments of the present application, the base plate 100 may be arranged in various manners, and for example, the base plate 100 may include a planarization layer 130 and a driving circuit layer 120 located at a side of the planarization layer 130 away from the first electrode layer 200. Optionally, the base plate 100 may further include a substrate 110 arranged at a side of the driving circuit layer 120 away from the planarization layer 130. Optionally, the driving circuit layer 120 may include a first insulating layer 121, a second insulating layer 122, and a third insulating layer 123 that are stacked. Exemplarily, the driving circuit layer 120 may further include a driving circuit, which may include a transistor 124, a storage capacitor 125, and drive signal lines for connecting the individual devices, etc. Herein, the transistor 124 may include a semiconductor, a gate 124a, and a source/drain 124b. The storage capacitor 125 may include a first electrode plate 125a and a second electrode plate 125b. As an example, the gate 124a and the first electrode plate 125a may be located at a side of the first insulating layer 121 facing the substrate 110, the second electrode plate 125b may be located between the first insulating layer 121 and the second insulating layer 122, and the source/drain 124b may be located between the second insulating layer 122 and the third insulating layer 123.

Optionally, at least a portion of an orthographic projection of the driving circuit on the substrate 110 may be located within an orthographic projection of the shielding structure 500 on the substrate 110.

Optionally, the touch control component 10a may include a touch control electrode and some signal lines connected with the touch control electrode, such as a touch control ground signal line, a touch control drive signal line, a touch control receive signal line, and the like.

Optionally, the touch control component 10a arranged in the non-display area NA and located at a side of the shielding structure 500 away from the base plate 100 may be shielded by the shielding structure 500 and is less likely to interfere with the signals in the driving circuit layer 120 in the display panel 10. For example, the shielding structure 500 can better shield the drive signal in the driving circuit layer 120 arranged in the non-display area NA, so that the touch control signal of the touch control component 10a is less likely to interfere with the drive signal in the driving circuit layer 120, and thus the working reliability of the display panel 10 can be improved.

In some embodiments of the present application, the shielding structure 500 may include an electrically conductive material. For example, the first shielding structure 510 and the second shielding structure 520 may include an electrically conductive material, thereby enhancing the blocking and shielding effect of the shielding structure 500 on the touch control signals and the drive signals in the display panel 10.

Optionally, the first shielding structure 510 and the isolation structure 400 may each include an electrically conductive material, so that the first shielding structure 510 and the isolation structure 400 may be prepared in a same process step, and adjacent second electrodes 710 may be interconnected through the isolation portion 400 to form a planar electrode, so as to facilitate the control of the second electrodes 710 in the display panel 10.

In some optional embodiments, under a condition that the shielding structure 500 is an electrically conductive shielding structure, the electrically conductive shielding structure 500 may be connected with a DC voltage signal end of the display panel 10. For example, the first shielding structure 510 or the second shielding structure 520 may be connected with the DC voltage signal end of the display panel 10. The shielding structure 500 is connected with the DC voltage signal end of the display panel 10, so that the DC voltage signal end can provide a stable voltage to the shielding structure 500, thereby enhancing the blocking and shielding effect of the shielding structure 500 on the touch control signals and the drive signals in the display panel 10, and thus the touch control signals and the drive signals in the display panel 10 are less likely to interfere with each other.

As shown in FIGS. 2 and 3, in some optional embodiments, a signal line of the DC voltage signal end may include at least one of a ground signal line, an initialization signal line, or a positive power supply voltage signal line, and the shielding structure 500 may be electrically insulated from the isolation structure 400, so that when at least one of a ground signal line, an initialization signal line, or a positive power supply voltage signal line transmits a signal to the shielding structure 500, the signal in the shielding structure 500 is less likely to affect the signal in the second electrode 710 in the display panel 10 through the isolation structure 400, thereby improving the reliability of light emitting and display of the display panel 10.

In this optional embodiment, the shielding structure 500 may be electrically insulated from the isolation structure 400 in various manners. For example, the shielding structure 500 may be spaced apart from the isolation structure 400, or an insulating material may be arranged between the shielding structure 500 and the isolation structure 400 to achieve the insulation, which is not specifically limited in the present application.

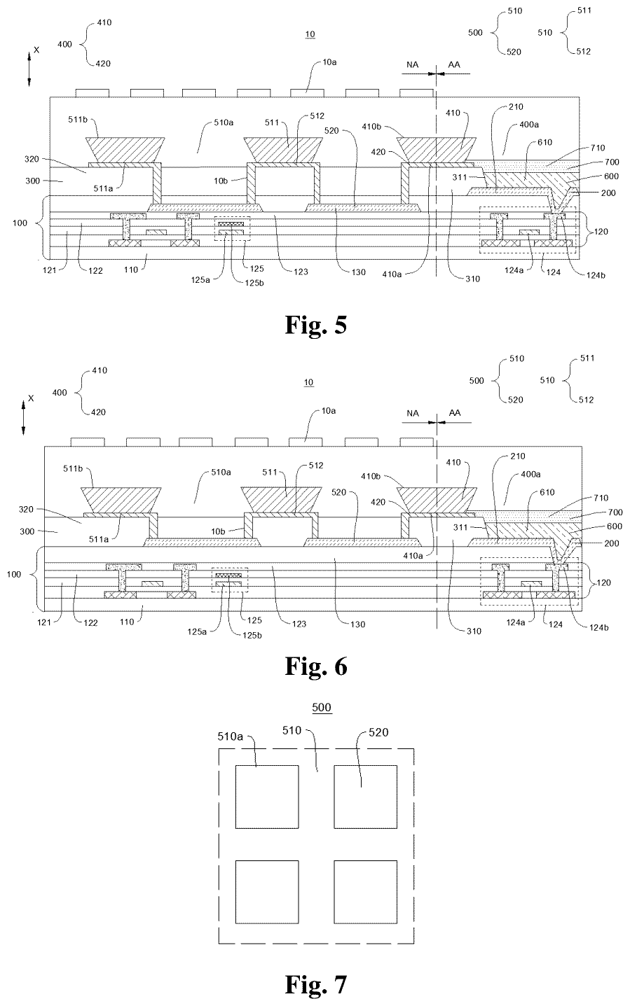

FIG. 4 shows a partial schematic structural diagram of a first shielding structure 510 and an isolation structure 400 according to another embodiment of the present application, and FIG. 5 shows a partial sectional view of a display panel 10 according to another embodiment of the present application.

As shown in FIGS. 4 and 5, in some other optional embodiments, the signal line of the DC voltage signal end may include a negative power supply voltage signal line, and the first shielding structure 510 may be connected with the isolation structure 400, so that the second electrode 710 in the display panel 10 may receive a negative power supply voltage signal (ELVSS) transmitted by the negative power supply voltage signal line through the isolation structure 400 and the first shielding structure 510 in sequence, so as to cause the display panel 10 to emit light and display, and facilitate the arrangement of the signal lines in the display panel 10.

Optionally, the first shielding structure 510 and the isolation structure 400 may form a one-piece structure, so that the first shielding structure 510 and the isolation structure 400 can be manufactured in a same process step, and thus the manufacturing process of the display panel 10 can be simplified, so as to increase the manufacturing efficiency of the display panel 10.

Optionally, the second shielding structure 520 may also be connected with the isolation structure 400, so as to reduce the resistance when the negative supply voltage signal is transmitted.

In some embodiments of the present application, the position of the second shielding structure 520 may be set in various manners, and the second shielding structure 520 is located at a side of the first shielding structure 510 facing the base plate 100. For example, the second shielding structure 520 may be arranged between the first shielding structure 510 and the driving circuit.

Optionally, since the second shielding structure 520 is located at a side of the first shielding structure 510 facing the base plate 100, the second shielding structure 520 may be connected with the DC voltage signal end, so that the shielding structure 500 is connected with the DC voltage signal end of the display panel 10. Herein, the first shielding structure 510 connected with the second shielding structure 520 may be connected with the DC voltage signal end through the second shielding structure 520.

As shown in FIG. 5, in some optional embodiments, the second shielding structure 520 may be arranged within the base plate 100. Optionally, the second shielding structure 520 may be arranged between any two film layers of the base plate 100 located at a side of the driving circuit away from the substrate 110. For example, the second shielding structure 520 may be arranged between the planarization layer 130 and the third insulating layer 123.

FIG. 6 shows a partial sectional view of a display panel 10 according to yet another embodiment of the present application.

As shown in FIG. 6, in some other optional embodiments, the second shielding structure 520 may be arranged at a side of the base plate 100 facing the first electrode layer 200, and for example, the second shielding structure 520 is arranged in the same layer as the first electrode layer 200. The second shielding structure 520 is arranged in the same layer as the first electrode layer 200, so that the second shielding structure 520 and the first electrode layer 200 can be manufactured in a same process step, and thus not only mutual interference between the touch control signals and other signals in the display panel 10 can be reduced through the second shielding structure 520, but also the manufacturing process of the display panel 10 can be simplified, so as to increase the manufacturing efficiency of the display panel 10.

Optionally, a shape of the second shielding structure 520 is the same as a shape of the first electrode 210, and a size of the second shielding structure 520 is the same as a size of the first electrode 210, so that the second shielding structure 520 and the first electrode 210 can be manufactured in a same process step using a same processing equipment, so as to further increase the manufacturing efficiency of the display panel 10.

For ease of description, in the following embodiments, for example, the second shielding structure 520 is arranged in the same layer as the first electrode layer 200.

In some optional embodiments, the isolation structure 400 may be configured to separate the materials of the adjacent light-emitting units 610 and to separate the materials of the adjacent second electrodes 710. Herein, the isolation structure 400 may enclose and form an isolation opening 400a, and an orthographic projection of the light-emitting unit 610 and the second electrode 710 on the isolation structure 400 may be located within the isolation opening 400a.

Optionally, the isolation structure 400 includes an isolation portion 410 including a first end portion 410a facing the base plate 100 and a second end portion 410b away from the base plate 100, an orthographic projection of the first end portion 410a on the base plate 100 is located within an orthographic projection of the second end portion 410b on the base plate 100.

In these optional embodiments, the orthographic projection of the first end portion 410a of the isolation structure 400 on the base plate 100 is located within the orthographic projection of the second end portion 410b of the isolation structure 400 on the base plate 100, so that during vapor deposition of the light-emitting layer 600 and the second electrode layer 700 of the display panel 10, the second end portion 410b can block at least a portion of the material for preparing the light-emitting layer 600, so as to separate the light-emitting layers 400 of adjacent sub-pixels and facilitate forming a plurality of light-emitting units 610 that are arranged at intervals, and thus no fine mask is required for the vapor deposition of the light-emitting layer 600 of the display panel 10. For example, no Fine Metal Mask (FMM) is required for the vapor deposition of the light-emitting layer 600, thereby reducing the cost for manufacturing the display panel 10.

FIG. 7 shows a schematic structural diagram of a shielding structure 500 according to an embodiment of the present application.

As shown in FIGS. 6 and 7, in some optional embodiments, the first shielding structure 510 encloses and forms a shielding opening 510a, and at least a portion of an orthographic projection of the second shielding structure 520 on the first shielding structure 510 is located within the shielding opening 510a.

With the shielding opening 510a, the first shielding structure 510 and the shielding opening 510a enclosed and formed by the first shielding structure 510 can be manufactured simultaneously when the isolation structure 400 and the isolation opening 400a enclosed and formed by the isolation structure 400 are manufactured, so that the first shielding structure 510 and the isolation structure 400 can be manufactured in a same process step, so as to increase the manufacturing efficiency of the display panel 10. At least a portion of the orthographic projection of the second shielding structure 520 on the first shielding structure 510 is located within the shielding opening 510a, so that the second shielding structure 520 can better block the shielding opening 510a in a thickness direction X of the display panel 10 to provide better blocking and shielding effect between the touch control signals and other signals in the display panel 10, and thus the touch control signals and other signals in the display panel 10 are less like to interfere with each other through the shielding opening 510a, thereby further improving the working reliability of the display panel 10.

Optionally, an orthographic projection of the shielding opening 510a on the base plate 100 is located within an orthographic projection of the second shielding structure 520 on the base plate 100, so as to further enhance the blocking effect of the second shielding structure 520 on the shielding opening 510a to provide better blocking and shielding effect between the touch control signals and other signals in the display panel 10.

Optionally, the shielding structure 500 includes a plurality of second shielding structures 520 arranged at intervals, and the first shielding structure 510 is arranged around at least a portion of the second shielding structures 520, so that the shape and arrangement of the second shielding structure 520 may be similar to the shape and arrangement of the first electrode 210, which facilitates manufacturing the second shielding structure 520 and the first electrode 210 together, i.e., facilitates manufacturing the second shielding structure 520 and the first electrode layer 200 in a same process step.

Optionally, the second shielding structure 520 and the first electrode 210 may be arranged in a same layer and formed with a same material, so as to further facilitate manufacturing the second shielding structure 520 and the first electrode layer 200 in a same process step.

In some optional embodiments, the shape of the first shielding structure 510 may be similar to the shape of the isolation structure 400, so that the shape of the shielding opening 510a enclosed and formed by the first shielding structure 510 may be similar to the shape of the isolation opening 400a enclosed and formed by the isolation structure 400, and the shielding opening 510a and the isolation opening 400a may be manufactured using a similar or a same manufacturing process, so as to manufacture the shielding opening 510a and the isolation opening 400a in a same process step, and thus the manufacturing process of the display panel 10 can be further simplified to increase the manufacturing efficiency of the display panel 10.

Optionally, the first shielding structure 510 includes a first sub-portion 511 arranged in the same layer as the isolation portion 410, the first sub-portion 511 includes a third end portion 511a facing the base plate 100 and a fourth end portion 511b away from the base plate 100, and an orthographic projection of the third end portion 511a on the base plate 100 is located within an orthographic projection of the fourth end portion 511b on the base plate 100, so that the shape of the first shielding structure 510 may be similar to the shape of the isolation structure 400, so as to facilitate manufacturing the first shielding structure 510 and the isolation structure 400 in a same process step.

In some embodiments of the present application, the shape of the isolation portion 410 and the shape of the first sub-portion 511 may be set in various manners. Herein, the shape of the isolation portion 410 may be any shape that can block and separate the material of the light-emitting layer 600.

As shown in FIG. 6, in some embodiments, in a direction away from the base plate 100, a distance between surfaces at two sides of the isolation portion 410 towards the light-emitting unit 610 is progressively increased, and a distance between surfaces at two sides of the first sub-portion 511 towards the second shielding structure 520 is progressively increased, so as to form a shape in which the orthographic projection of the first end portion 410a of the isolation portion 410 on the base plate 100 is located within the orthographic projection of the second end portion 410b on the base plate 100, and form a shape in which the orthographic projection of the third end portion 511a of the first sub-portion 511 on the base plate 100 is located within an orthographic projection of the fourth end portion 511b on the base plate 100.

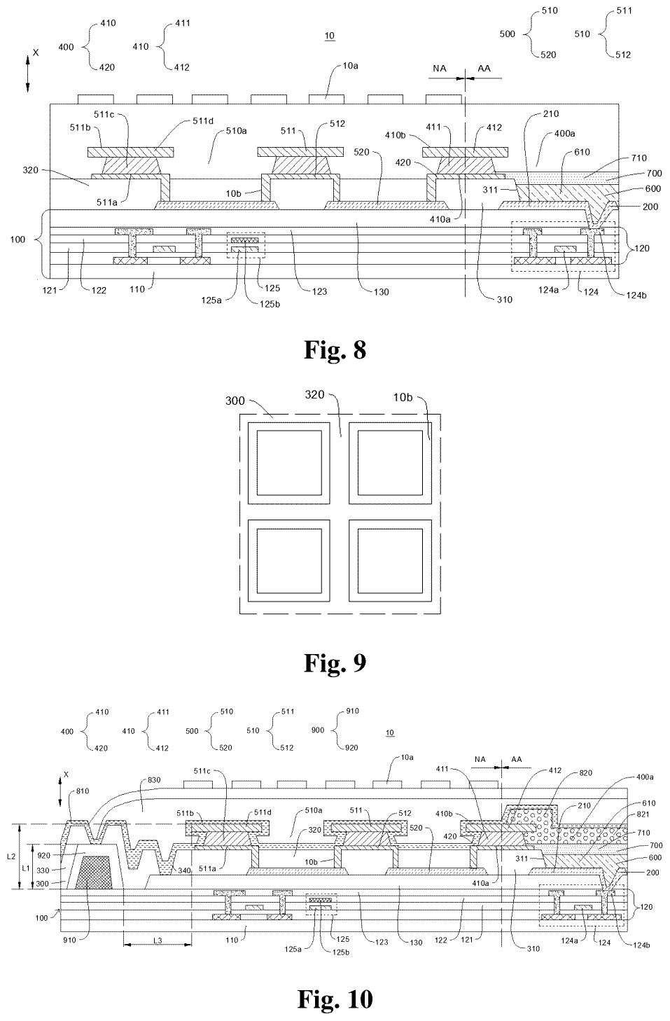

FIG. 8 shows a partial sectional view of a display panel 10 according to yet another embodiment of the present application.

As shown in FIG. 8, in some other embodiments, the isolation structure 400 includes a first isolation portion 411 and a second isolation portion 412 arranged at a side of the first isolation portion 411 away from the base plate 100, an orthographic projection of the first isolation portion 411 on the base plate 100 is located within an orthographic projection of the second isolation portion 412 on the base plate 100, and the second isolation portion 412 protrudes towards the light-emitting unit 610 from the first isolation portion 411; and the first sub-portion 511 includes a first shielding portion 511c and a second shielding portion 511d arranged at a side of the first shielding portion 511c away from the base plate, an orthographic projection of the first shielding portion 511c on the base plate 100 is located within an orthographic projection of the second shielding portion 511d on the base plate 100, and the second shielding portion 511d protrudes towards the shielding opening 510a from the first shielding portion 511c.

Optionally, the first end portion 410a may be located at the first isolation portion 411, and the second end portion 410b may be located at the second isolation portion 412. Optionally, the third end portion 511a may be located at the first shielding portion 511c, and the fourth end portion 511b may be located at the second shielding portion 511d.

The second isolation portion 412 can protrude towards the light-emitting unit 610 from the first isolation portion 411, that is, the second isolation portion 412 can protrude towards the isolation opening 400a from the first isolation portion 411, so that the second isolation portion 412 can better block and separate the material of the light-emitting layer 600, and thus the material of the light-emitting layer 600 is less likely to be continuous between the second isolation portion 412 and the first isolation portion 411, thereby further enhancing the separating effect of the isolation structure 400 on the material of the light-emitting layer 600.

Optionally, the first shielding portion 511c and the first isolation portion 411 are arranged in a same layer and formed with a same material, or the second shielding portion 511d and the second isolation portion 412 are arranged in a same layer and formed with a same material, so as to facilitate manufacturing the first sub-portion 511 and the isolation portion 410 in a same process step.

As shown in FIG. 8, in some optional embodiments, the first shielding structure 510 may be connected with the second shielding structure 520 through a via 10b, so that a capacitor is less likely to be generated between the first shielding structure 510 and the second shielding structure 520, and the shielding structure 500 itself is less likely to interfere with the touch control signals in the touch control component 10a and the signals in the base plate 100, and thus the working reliability of the display panel 10 can be improved.

FIG. 9 shows a partial schematic structural diagram of a second pixel definition portion 320 according to an embodiment of the present application.

As shown in FIGS. 8 and 9, optionally, the via 10b may be arranged around at least a portion of the second shielding structure 520, so that the material in the via 10b for connecting the first shielding structure 510 and the second shielding structure 520 may further provide better blocking and shielding effect between the touch control signals and other signals in the display panel 10, and thus the touch control signals and other signals in the display panel 10 are less likely to interfere with each other at the gap between the first shielding structure 510 and the second shielding structure 520, thereby further improving the working reliability of the display panel 10.

For example, the via 10b may be arranged around at least a portion of the second shielding structure 520, and at least a portion of the first shielding structure 510 may fall into the via 10b and be connected with the second shielding structure 520, so that the first shielding structure 510 in the via 10b may also provide better blocking and shielding effect between the touch control signals and other signals in the display panel 10, and thus the touch control signals and other signals in the display panel 10 are less likely to interfere with each other at the gap between the first shielding structure 510 and the second shielding structure 520, and the shielding structure 500 can provide blocking and shielding effect at the non-display area NA more continuously.

Optionally, an orthographic projection of the first shielding structure 510 on the base plate 100 at least partially overlaps an orthographic projection of the second shielding structure 520 on the base plate 100, so that the first shielding structure 510 can be connected with the second shielding structure 520 through the via 10b.

In some optional embodiments, the first shielding structure 510 includes a first sub-portion 511 and a second sub-portion 512 located at a side of the first sub-portion 511 facing the base plate 100, and the second sub-portion 512 is connected with the second shielding structure 520 through the via 10b.

Optionally, the second sub-portion 512 protrudes towards the shielding opening 510a from the first sub-portion 511.

Optionally, an orthographic projection of the second sub-portion 512 on the base plate 100 at least partially overlaps the orthographic projection of the second shielding structure 520 on the base plate 100.

The second sub-portion 512 protrudes towards the shielding opening 510a from the first sub-portion 511, so that the second sub-portion 512 can have a better extension dimension and be located above the second shielding structure 520, that is, the orthographic projection of the second sub-portion 512 on the base plate 100 can at least partially overlap the orthographic projection of the second shielding structure 520 on the base plate 100, and thus the second sub-portion 512 can be connected with the second shielding structure 520 through the via 10b, so as to achieve the connection between the first shielding structure 510 and the second shielding structure 520.

Optionally, the isolation structure 400 includes an isolation portion 410 and an electrically conductive portion 420 located at a side of the isolation portion 410 facing the base plate 100, and the electrically conductive portion 420 protrudes towards the light-emitting unit 610 from the isolation portion 410. The electrically conductive portion 420 protrudes towards the light-emitting unit 610 from the isolation portion 410, that is, the electrically conductive portion 420 protrudes towards the isolation opening 400a from the isolation portion 410, so that the second electrode 710 can contact the electrically conductive portion 420, the contacting area between the electrically conductive portion 420 and the second electrode 710 can be increased, and the contacting resistance of the display panel 10 can be reduced, so as to facilitate the electrical connection between adjacent second electrodes 710 through the isolation portion 410.

Optionally, the second sub-portion 512 and the electrically conductive portion 420 are arranged in a same layer and formed with a same material, so that the second sub-portion 512 and the electrically conductive portion 420 can be manufactured in a same process step.

As shown in FIGS. 8 and 9, in some optional embodiments, the display panel 10 further includes a pixel definition layer 300 arranged at a side of the first electrode layer 200 away from the base plate 100, the pixel definition layer 300 includes a first pixel definition portion 310 located in the display area AA and a second pixel definition portion 320 located in the non-display area NA, the first pixel definition portion 310 includes a pixel opening 311, at least a portion of the first electrode 210 is exposed from the pixel opening 311, and at least a portion of the second pixel definition portion 320 is located at a side of the second shielding structure 520 away from the base plate 100.

Optionally, the first shielding structure 510 is arranged at a side of the second pixel definition portion 320 away from the base plate 100, the first shielding structure 510 is connected with the second shielding structure 520 through a via 10b penetrating through the second pixel definition portion 320.

In these optional embodiments, at least a portion of the light-emitting unit 610 may be arranged within the pixel opening 311, and the first electrode 210 exposed from the pixel opening 311 of the first pixel definition portion 310 may be used to participate in driving the light-emitting unit 610 to emit light. At least a portion of the second pixel definition portion 320 is located at a side of the second shielding structure 520 away from the base plate 100, so that when the first shielding structure 510 is manufactured, for example, when the shielding opening 510a is manufactured, the second pixel definition portion 320 can provide better protection for the second shielding structure 520, and thus the etching material is less likely to damage the second shielding structure 520.

In some optional embodiments, the second pixel definition portion 320 includes at least one through hole 340 penetrating through the second pixel definition portion 320, which may be used to release water vapor in the display panel 10, so that the display panel 10 will not be damaged by the pressure of the water vapor. For example, the through hole 340 may be used to release water vapor generated during the manufacturing process (e.g., baking) of a portion of the organic material layer structures (such as the planarization layer 130) of the display panel 10, and the through hole 340 may be further used to release water vapor generated during a reliability test (simulation of a user usage scenario) of the display panel 10.

Optionally, the through hole 340 may be located at a side of the shielding structure 500 away from the display area AA.

Optionally, an orthographic projection of the shielding structure 500 on the pixel definition layer 300 is spaced apart from the through hole 340.

By suitably setting the position of the through hole 340, the through hole 340 is less likely to affect the continuity of the shielding structure 500, so that the shielding structure 500 can better prevent the signal in the base plate 100 from being transmitted to the touch control component 10a.

In some optional embodiments, the through hole 340 may be arranged around at least a portion of the shielding structure 500, so that the through hole 340 may have a better extension dimension to enhance the releasing effect of the through hole 340 on water vapor.

In this optional embodiment, the shape of the through hole 340 may be set in various manners. For example, the through hole 340 may be a ring in shape to better surround the shielding structure 500. Alternatively, for example, the second pixel definition portion 320 includes a plurality of through holes 340 arranged at intervals around the shielding structure 500.

FIG. 10 shows a partial sectional view of a display panel 10 according to yet another embodiment of the present application.

As shown in FIG. 10, in some optional embodiments, the display panel 10 further includes a first encapsulation layer 810, and at least a portion of the first encapsulation layer 810 is arranged at a side of the shielding structure 500 away from the base plate 100.

Optionally, the first encapsulation layer 810 includes an inorganic material.

In these optional embodiments, the shielding structure 500 is covered by the first encapsulation layer 810, so that during subsequent preparation of other film layers of the display panel 10, the first encapsulation layer 810 can be covered and adhered by the material of other film layers better than the electrically conductive material (such as the metal material) of the shielding structure 500, and thus the peeling and falling of the subsequently prepared film layers is less likely to occur, thereby improving the structural reliability of the display panel 10.

Optionally, the display panel 10 further includes a third encapsulation layer 830 arranged at a side of the first encapsulation layer 810 away from the base plate 100, which may be also used for encapsulation of the display panel 10. Optionally, the third encapsulation layer 830 includes an organic material, that is, the third encapsulation layer 830 may be an organic encapsulation layer. The overall thickness of the display panel 10 may be adjusted such that the surface of the third encapsulation layer 830 away from the base plate 100 is smoother.

In these optional embodiments, the shielding structure 500 is covered by the first encapsulation layer 810, so that during subsequent preparation of the third encapsulation layer 830 of the display panel 10, the first encapsulation layer 810 can be covered and adhered by the material of the third encapsulation layer 830 better than the electrically conductive material (such as the metal material) of the shielding structure 500, and thus the peeling and falling of the subsequently prepared third encapsulation layer 830 is less likely to occur, thereby improving the structural reliability of the display panel 10.

Optionally, the display panel 10 further includes a second encapsulation layer 820, and the second encapsulation layer 820 includes a second encapsulation portion 821 located in the display area AA and arranged at a side of the light-emitting layer 600 away from the base plate 100. Specifically, the second encapsulation portion 821 may be located at a side of the second electrode 710 away from the base plate 100. With the second encapsulation layer 820, the light-emitting unit 610 and the second electrode 710 within the isolation opening 400a can be better encapsulated by the second encapsulation portion 821, and thus the external interfering substances (such as water vapor) are less likely to damage the light-emitting unit 610 and the second electrode 710 within the isolation opening 400a, thereby improving the working reliability of the display panel 10.

In some embodiments, during the preparation of the display panel 10, the second encapsulation layer 820 may be prepared firstly, followed by the preparation of the first encapsulation layer 810 as a whole. That is, the first encapsulation layer 810 may be arranged in both the display area AA and the non-display NA, so that the first encapsulation layer 810 can have a better coverage effect, and at least a portion of the first encapsulation layer 810 can be arranged at a side of the second encapsulation layer 820 away from the base plate 100, and thus the first encapsulation layer 810 can also better participate in the encapsulation of the light-emitting unit 610 and the second electrode 710 within the isolation opening 400a, so as to further improve the encapsulation effect on the display panel 10.

Optionally, the second encapsulation layer 820 includes an inorganic material.

Optionally, a material of the first encapsulation layer 810 is the same as a material of the second encapsulation layer 820, so that the first encapsulation layer 810 can be better adhered to the second encapsulation layer 820, and thus the peeling and falling of the first encapsulation layer 810 is less likely to occur.

Optionally, a thickness of the first encapsulation layer 810 may be less than a thickness of the second encapsulation layer 820, so that the first encapsulation layer 810 located in the non-display area NA is less likely to have an excessive thickness, thereby reducing the effect of the first encapsulation layer 810 on subsequent preparation of the display panel 10, e.g., the effect of the first encapsulation layer 810 on subsequent cutting or bending process can be reduced.

As shown in FIG. 10, in some optional embodiments, the display panel 10 further includes a dam 900 located in the non-display area NA and arranged at a side of the base plate 100 facing the first electrode layer 200, and the dam 900 is arranged around at least a portion of the shielding structure 500. With the dam 900, the organic material in the third encapsulation layer 830 can be better confined within the dam 900.

Optionally, the dam 900 may be arranged at a side of the driving circuit layer 120 facing the planarization layer 130. Optionally, the dam 900 may be spaced apart from the planarization layer 130, which facilitates the limitation of the organic material in the third encapsulation layer 830 by the dam 900.

Optionally, at least a portion of the dam 900 and the planarization layer 130 may be arranged in a same layer and formed with a same material, so as to further simplify the manufacturing process of the display panel 10 and increase the manufacturing efficiency of the display panel 10. For example, the dam 900 may be formed from a stack of multiple layers of materials, and in a direction away from the driving circuit layer 120, the dam 900 may include a first dam layer 910 and a second dam layer 920 that are stacked in sequence. Herein, at least a portion of the material of the planarization layer 130 may fall onto the first dam layer 910 to form the second dam layer 920 when the planarization layer 130 is prepared.

Optionally, the pixel definition layer 300 further includes a third pixel definition portion 330 arranged above the second dam layer 920, and the third pixel definition portion 330 may also include a through hole 340 for releasing water vapor in the display panel 10, so that the display panel 10 is less likely to be damaged by the pressure of the water vapor.

In some optional embodiments, a first spacing L1 is between a surface of the dam 900 at a side away from the driving circuit layer 120 and a surface of the driving circuit layer 120 at a side facing the planarization layer 130, a maximum spacing between a surface of the shielding structure 500 at a side away from the driving circuit layer 120 and the surface of the driving circuit layer 120 at a side facing the planarization layer 130 is a second spacing L2, and the second spacing L2 is greater than the first spacing L1.

Optionally, a third spacing L3 is between an orthographic projection of the shielding structure 500 on the base plate 100 and an orthographic projection the dam 900 on the base plate 100, and the third spacing L3 is greater than or equal to 100 μm.

Optionally, the third spacing L3 is greater than or equal to 100 μm and less than or equal to 150 μm. For example, the third spacing L3 may be equal to 120 μm, 130 μm, 140 μm, or 150 μm.

In these optional embodiments, if there is a height difference between the dam 900 in the non-display area NA and the shielding structure 500, i.e., if the second spacing L2 is greater than the first spacing L1, a relatively sufficient buffer space can exist between the dam 900 and the shielding structure 500 by suitably setting the third spacing L3, so as to facilitate progressively reducing the thickness of the third encapsulation layer 830 in the buffer space, so that when the third encapsulation layer 830 is manufactured, the material of the third encapsulation layer 830 flowing to the dam 900 is less likely to have an excessive thickness, and thus the dam 900 can better limit the organic material in the third encapsulation layer 830.

The embodiments of the second aspect of the present application provide a display apparatus including the display panel 10 according to any of the above embodiments. Since the display apparatus according to the embodiments of the second aspect of the present application includes the display panel 10 according to any of the above embodiments of the first aspect, the display apparatus has the beneficial effect of the display panel 10, which will not be repeated herein.

The display apparatus in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. A display panel with a display area and a non-display area, the display panel comprising:
a base plate comprising at least one of a signal line or a driving circuit in the non-display area;
a first electrode layer arranged at one side of the base plate and comprising a first electrode located in the display area;
a light-emitting layer comprising a light-emitting unit located at a side of the first electrode away from the base plate;
an isolation structure arranged at a side of the base plate facing the first electrode layer, the isolation structure being located in the display area and arranged around at least a portion of the light-emitting unit;
a shielding structure located in the non-display area and comprising a first shielding structure and at least one second shielding structure that are electrically connected with each other, at least a portion of the first shielding structure being arranged in the same layer as the isolation structure, and the second shielding structure being located in a different film layer from the first shielding structure; and
a touch control component, at least a portion of the touch control component being located at a side of the shielding structure away from the base plate.

2. The display panel according to claim 1, wherein the second shielding structure is located at a side of the first shielding structure facing the base plate.

3. The display panel according to claim 1, wherein the second shielding structure is arranged within the base plate, or the second shielding structure is arranged in the same layer as the first electrode layer.

4. The display panel according to claim 1, wherein the second shielding structure is arranged in the same layer as the first electrode layer, and a shape of the second shielding structure is the same as a shape of the first electrode; and a size of the second shielding structure is the same as a size of the first electrode.

5. The display panel according to claim 1, wherein the first shielding structure encloses and forms a shielding opening, and at least a portion of an orthographic projection of the second shielding structure on the first shielding structure is located within the shielding opening;
the shielding structure comprises a plurality of second shielding structures arranged at intervals, and the first shielding structure is arranged around at least a portion of the second shielding structures;
an orthographic projection of the shielding opening on the base plate is located within an orthographic projection of the second shielding structure on the base plate.

6. The display panel according to claim 1, wherein the isolation structure comprises an isolation portion comprising a first end portion facing the base plate and a second end portion away from the base plate, an orthographic projection of the first end portion on the base plate is located within an orthographic projection of the second end portion on the base plate, the first shielding structure comprises a first sub-portion arranged in the same layer as the isolation portion, the first sub-portion comprises a third end portion facing the base plate and a fourth end portion away from the base plate, and an orthographic projection of the third end portion on the base plate is located within an orthographic projection of the fourth end portion on the base plate;
in a direction away from the base plate, a distance between surfaces at two sides of the isolation portion towards the light-emitting unit is progressively increased, and a distance between surfaces at two sides of the first sub-portion towards the second shielding structure is progressively increased;
the isolation structure comprises a first isolation portion and a second isolation portion arranged at a side of the first isolation portion away from the base plate, an orthographic projection of the first isolation portion on the base plate is located within an orthographic projection of the second isolation portion on the base plate, and the second isolation portion protrudes towards the light-emitting unit from the first isolation portion;
the first sub-portion comprises a first shielding portion and a second shielding portion arranged at a side of the first shielding portion away from the base plate, an orthographic projection of the first shielding portion on the base plate is located within an orthographic projection of the second shielding portion on the base plate, and the second shielding portion protrudes towards the shielding opening from the first shielding portion; and
the first shielding portion and the first isolation portion are arranged in a same layer and formed with a same material, or the second shielding portion and the second isolation portion are arranged in a same layer and formed with a same material.

7. The display panel according to claim 1, wherein the first shielding structure is connected with the second shielding structure.

8. The display panel according to claim 1, wherein the first shielding structure is connected with the second shielding structure through a via;
the via is arranged around at least a portion of the second shielding structure;
an orthographic projection of the first shielding structure on the base plate at least partially overlaps an orthographic projection of the second shielding structure on the base plate.

9. The display panel according to claim 8, wherein the first shielding structure comprises a first sub-portion and a second sub-portion located at a side of the first sub-portion facing the base plate, and the second sub-portion is connected with the second shielding structure through the via;
the first shielding structure encloses and forms a shielding opening, and the second sub-portion protrudes towards the shielding opening from the first sub-portion;
an orthographic projection of the second sub-portion on the base plate at least partially overlaps the orthographic projection of the second shielding structure on the base plate;
the isolation structure comprises an isolation portion and an electrically conductive portion located at a side of the isolation portion facing the base plate, and the electrically conductive portion protrudes towards the light-emitting unit from the isolation portion; and
the second sub-portion and the electrically conductive portion are arranged in a same layer and formed with a same material.

10. The display panel according to claim 1, further comprising a pixel definition layer arranged at a side of the first electrode layer away from the base plate, wherein the pixel definition layer comprises a first pixel definition portion located in the display area and a second pixel definition portion located in the non-display area, the first pixel definition portion comprises a pixel opening, at least a portion of the first electrode is exposed from the pixel opening, and at least a portion of the second pixel definition portion is located at a side of the second shielding structure away from the base plate; and
the first shielding structure is arranged at a side of the second pixel definition portion away from the base plate, the first shielding structure is connected with the second shielding structure through a via penetrating through the second pixel definition portion.

11. The display panel according to claim 10, wherein the second pixel definition portion comprises at least one through hole penetrating through the second pixel definition portion;
the through hole is located at a side of the shielding structure away from the display area;
an orthographic projection of the shielding structure on the pixel definition layer is spaced apart from the through hole;
the through hole is arranged around at least a portion of the shielding structure; and
the second pixel definition portion comprises a plurality of through holes arranged at intervals around the shielding structure.

12. The display panel according to claim 1, further comprising a first encapsulation layer, wherein at least a portion of the first encapsulation layer is arranged at a side of the shielding structure away from the base plate;
an orthographic projection of the shielding structure on the base plate is located within an orthographic projection of the first encapsulation layer on the base plate;
the first encapsulation layer comprises an inorganic material.

13. The display panel according to claim 12, further comprising a second encapsulation layer, wherein the second encapsulation layer comprises a second encapsulation portion located in the display area and arranged at a side of the light-emitting layer away from the base plate;
at least a portion of the first encapsulation layer is further arranged at a side of the second encapsulation layer away from the base plate;
the second encapsulation layer comprises an inorganic material;
a material of the first encapsulation layer is the same as a material of the second encapsulation layer;
a thickness of the first encapsulation layer is less than a thickness of the second encapsulation layer.

14. The display panel according to claim 12, further comprising a third encapsulation layer arranged at a side of the first encapsulation layer away from the base plate; and
the third encapsulation layer comprising an organic material.

15. The display panel according to claim 1, wherein the non-display area is arranged around at least a portion of the display area.

16. The display panel according to claim 1, further comprising a dam located in the non-display area and arranged at a side of the base plate facing the first electrode layer, wherein the dam is arranged around at least a portion of the shielding structure;
the base plate comprises a planarization layer and a driving circuit layer located at a side of the planarization layer away from the first electrode layer, and the dam is arranged at a side of the driving circuit layer facing the planarization layer;
a first spacing is between a surface of the dam at a side away from the driving circuit layer and a surface of the driving circuit layer at a side facing the planarization layer, a maximum spacing between a surface of the shielding structure at a side away from the driving circuit layer and the surface of the driving circuit layer at a side facing the planarization layer is a second spacing, and the second spacing is greater than the first spacing;
a third spacing is between an orthographic projection of the shielding structure on the base plate and an orthographic projection the dam on the base plate, and the third spacing is greater than or equal to 100 μm.

17. The display panel according to claim 16, wherein the third spacing is greater than or equal to 100 μm and less than or equal to 150 μm.

18. The display panel according to claim 16, wherein the third spacing is equal to 120 μm, 130 μm, 140 μm, or 150 μm.

19. The display panel according to claim 1, wherein the shielding structure is an electrically conductive shielding structure, and the electrically conductive shielding structure is connected with a DC voltage signal end of the display panel;
a signal line of the DC voltage signal end comprises at least one of a ground signal line, an initialization signal line, or a positive power supply voltage signal line, and the electrically conductive shielding structure is electrically insulated from the isolation structure;
the signal line of the DC voltage signal end comprises a negative power supply voltage signal line, and the first shielding structure is connected with the isolation structure; and
the first shielding structure and the isolation structure form a one-piece structure.

20. A display apparatus, comprising the display panel according to claim 1.
